(19) United States
(12) Patent Application Publication
(10) Pub. No.: US 2025/0329622 A1
(43) Pub. Date: Oct. 23, 2025

(54) CIRCUIT BOARD AND SEMICONDUCTOR PACKAGE COMPRISING SAME

(71) Applicant: LG INNOTEK CO., LTD., Seoul (KR)

(72) Inventors: Chae Young YOU, Seoul (KR); Han Sang KIM, Seoul (KR); Jae Man PARK, Seoul (KR)

(21) Appl. No.: 18/865,493

(22) PCT Filed: May 15, 2023
(86) PCT No.: PCT/KR2023/006539

§ 371 Date: Nov. 13, 2024

(30) Foreign Application Priority Data
May 13, 2022 (KR) 10-2022-0058990

(51) Int. Cl. H01L 23/498; H05K 1/02; H05K 1/11

(52) U.S. Cl. CPC H01L 23/498; H05K 1/0298; H05K 1/115; H05K 2201/096

(57) ABSTRACT

A circuit board according to an embodiment includes a first insulating layer; a first circuit layer disposed on the first insulating layer; a first buffer layer disposed on the first circuit layer; and a second insulating layer disposed on the first insulating layer and the first buffer layer, wherein the first circuit layer includes a surface layer including nitrogen (N), and the first buffer layer includes a first functional group bonded to the surface layer; and a second functional group bonded to the second insulating layer.

### TECHNICAL FIELD

An embodiment relates to a circuit board and a semiconductor package including the same.

### BACKGROUND ART

Components mounted on a circuit board transmit and receive signals through circuit patterns disposed on the circuit board. At this time, in recent years, with high functionalization of portable electronic devices, etc., high frequency of signals is in progress for high-speed processing of large amounts of information. Accordingly, circuit boards suitable for high-frequency applications are being demanded. Here, a circuit board suitable for high-frequency applications must include a low roughness circuit pattern that can transmit high-frequency signals without signal transmission loss. In other words, the circuit pattern must minimize signal transmission loss so that signal transmission is possible while maintaining a quality of high-frequency signals.

At this time, the transmission loss of the circuit pattern of the circuit board is mainly composed of conductor loss caused by a metal thin film such as copper and dielectric loss caused by an insulator such as an insulating layer.

The conductor loss caused by the metal thin film is related to a surface roughness of the circuit pattern. In other words, as the surface roughness of the circuit pattern increases, the transmission loss may increase due to a skin effect.

At this time, reducing the surface roughness of the circuit pattern has the effect of minimizing transmission loss, but there is a problem that a bonding strength or adhesion between the circuit pattern and the insulating layer is reduced.

Meanwhile, the frequency band used in communication systems over 5G is gradually increasing in order to achieve a high data transmission rate. For example, communication systems over 5G use ultra-high frequency (mm-Wave) bands (sub 6 gigabit (6 GHz), 28 gigabit (28 GHz), 38 gigabit (38 GHz) or higher frequencies).

Therefore, low roughness of the circuit pattern included in the circuit board is required.

However, as described above, when the roughness of the circuit pattern is lowered, a problem of bonding strength with the insulating layer occurs. In addition, when the roughness of the circuit pattern is increased, a problem of increased signal transmission loss occurs.

Accordingly, a new circuit pattern surface treatment technique that can improve the bonding strength between the circuit pattern and the insulating layer while lowering the surface roughness of the circuit pattern is required.
(Patent Document 1) KR 10-2010-0005881 A

### DISCLOSURE

### Technical Problem

The embodiment provides a circuit board capable of minimizing signal transmission loss and a semiconductor package including the same.

In addition, the embodiment provides a circuit board having improved adhesion between an insulating layer and a circuit layer and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises 1. A circuit board comprising: a first insulating layer; a first circuit layer disposed on the first insulating layer; a first buffer layer disposed on the first circuit layer; and a second insulating layer disposed on the first insulating layer and the first buffer layer, wherein the first circuit layer includes a surface layer including nitrogen (N), and wherein the first buffer layer includes: a first functional group bonded to the surface layer; and a second functional group bonded to the second insulating layer.

In addition, the surface layer of the first circuit layer is a nitride layer formed at a surface of the first circuit layer.

In addition, the nitride layer of the first circuit layer includes a third functional group including nitrogen (N) that coordinately bonds with the first functional group of the first buffer layer.

In addition, the first functional group includes at least one azole group among diazole, triazole, tetra azole, benzo triazole, benzo thiazole, and nitro triazole.

In addition, the second functional group includes a siloxane group covalently bonded to the second insulating layer.

In addition, the first buffer layer is formed with an organic silane agent including an azole group corresponding to the first functional group.

In addition, the first insulating layer includes a first region overlapping the first circuit layer in a thickness direction, and a second region excluding the first region, and a fourth functional group including nitrogen (N) is provided on an upper surface of the second region of the first insulating layer.

In addition, the first circuit layer includes a first surface in contact with the first buffer layer, and a roughness (Ra) of the first surface of the first circuit layer satisfies a range of 0.1 um to 0.9 um.

In addition, the first circuit layer includes a second surface in contact with the first insulating layer, and a roughness (Ra) of the second surface of the first circuit layer is different from the roughness (Ra) of the first surface.

In addition, a roughness (Ra) of the first buffer layer corresponds to the roughness (Ra) of the first surface of the first circuit layer.

In addition, the circuit board further includes a through electrode passing through at least one of the first insulating layer and the second insulating layer, and a roughness (Ra) of a side surface of the through electrode is different from the roughness (Ra) of the first surface of the first circuit layer.

In addition, an adhesion (90° Peel Strength) between the first circuit layer and the second insulating layer has a range of 0.55 to 1.5 kgf/cm.

In addition, the circuit board further comprises a second circuit layer disposed on an upper surface of the second insulating layer; a second buffer layer disposed on the second circuit layer; and a first protective layer disposed on the second insulating layer and the second buffer layer, and the second buffer layer has a functional group corresponding to the first and second functional groups of the first buffer layer.

In addition, the first buffer layer further includes a metal ion that coordinates with one of the first functional group and the third functional group.

Meanwhile, a semiconductor package according to an embodiment comprises a first insulating layer; a first circuit layer disposed on the first insulating layer; a first buffer layer disposed on the first circuit layer; a second insulating layer disposed on the first insulating layer and the first buffer layer; a second circuit layer disposed on the second insulating layer; a second buffer layer disposed on the second circuit layer; a first protective layer disposed on the second insulating layer and the second buffer layer and including an opening; a first connection part disposed on the second circuit layer overlapping the opening of the first protective layer in a thickness direction; and a chip mounted on the first connection part, wherein each of the first and second circuit layers includes a surface layer including nitrogen (N), each of the first and second buffer layers includes: a first functional group bonded to a surface layer of one of the first and second circuit layers; and a second functional group bonded to the second insulating layer, each of the first and second buffer layers includes a metal ion that coordinately bonds with the first functional group and the surface layer.

### Advantageous Effects

The embodiment can improve the reliability of the circuit board.

Preferably, the embodiment can improve the electrical reliability and physical reliability of the circuit board.

To this end, the embodiment forms a functional group including nitrogen on a surface of a circuit layer disposed on a first insulating layer. For example, the embodiment forms a nitride layer by plasma-treating the surface of the circuit layer. In addition, the embodiment forms a buffer layer on the nitride layer of the circuit layer.

The buffer layer includes a first functional group bonded to the circuit layer and a second functional group bonded to a second insulating layer disposed on the circuit layer. The first functional group may be an azole group. The first functional group may be coordinately bonded with a functional group including nitrogen (N) formed on the surface of the circuit layer. In addition, the second functional group may be covalently bonded with a functional group included in the second insulating layer. To this end, the buffer layer may be formed of an organic silane agent including an azole group.

Through this, the embodiment can improve an adhesion between the circuit layer and the second insulating layer by using the buffer layer. Through this, the embodiment can solve a physical reliability problem in which the second insulating layer is peeled off from the circuit layer.

At this time, the embodiment also performs plasma treatment on an upper surface of the first insulating layer during plasma treatment of the circuit layer. Accordingly, a functional group including nitrogen (N) can be formed on the upper surface of the first insulating layer. In addition, the functional group formed on the upper surface of the first insulating layer can be shared with the functional group of the second insulating layer. Accordingly, the embodiment can improve not only the adhesion between the circuit layer and the second insulating layer, but also the adhesion between the first insulating layer and the second insulating layer.

In addition, the buffer layer of the embodiment includes a metal ion. Preferably, the buffer layer includes a copper ion. At this time, the copper ion can coordinately bond with the functional group including nitrogen (N) of the circuit layer. Through this, the embodiment can further improve the adhesion between the buffer layer and the circuit layer.

Furthermore, the copper ion included in the buffer layer can coordinately bond with the first functional group of the buffer layer. Through this, the embodiment can strengthen an internal cohesion of the buffer layer through the coordination bond between the first functional group and the copper ion. Accordingly, the embodiment can further improve the adhesion between the circuit layer and the second insulating layer.

Meanwhile, the embodiment secures the adhesion between the circuit layer and the second insulating layer by using the functional group of the circuit layer and the first and second functional groups of the buffer layer. By this, the embodiment does not require an additional roughness imparting process for securing the adhesion to the circuit layer. Accordingly, the embodiment can prevent deformation of the circuit layer, and further improve the electrical characteristics of the circuit layer.

In addition, the embodiment can make a surface of the circuit layer have a fine roughness. This can be achieved by lowering the roughness of the surface of the circuit layer by securing the adhesion using the buffer layer. By this, the circuit layer of the embodiment can satisfy a surface roughness (Ra) of 0.1 um to 0.9 um. Accordingly, the embodiment can minimize transmission loss of a signal transmitted through the circuit layer. Furthermore, the embodiment can provide a circuit board applicable to a product using a high-frequency band.

### DESCRIPTION OF DRAWINGS

FIG. 1 is a cross-sectional view showing a circuit board according to a comparative example.

FIG. 2 is a view for explaining a signal transmission flow according to frequencies.

FIG. 3 is a cross-sectional view showing a circuit board according to a first embodiment.

FIG. 4 is a views for explaining a bonding relationship between a circuit layer, a buffer layer, and a second insulating layer according to an embodiment.

FIG. 5 and FIG. 6 are views for explaining a method for measuring adhesion (90° Peel Strength) of a circuit board according to an embodiment.

FIG. 7 is a cross-sectional view showing a circuit board according to a second embodiment.

FIG. 8 is a cross-sectional view showing a circuit board according to a third embodiment.

FIG. 9 is a cross-sectional view showing a layer structure of a circuit layer and a through electrode according to a first embodiment.

FIG. 10 is a cross-sectional view showing a layer structure of a circuit layer and an electrode according to a second embodiment.

FIG. 11 is a view showing a semiconductor package according to an embodiment.

FIG. 12 to FIG. 17 are views showing a method of manufacturing a circuit board according to an embodiment in order of processes.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and redisposed.

In addition, unless expressly otherwise defined and described, the terms used in the embodiments of the present invention (including technical and scientific terms may be construed the same meaning as commonly understood by one of ordinary skill in the art to which this invention belongs, and the terms such as those defined in commonly used dictionaries may be interpreted as having a meaning that is consistent with their meaning in the context of the relevant art.

Further, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Before describing the embodiment, a circuit board of a comparative example will be described.

### COMPARATIVE EXAMPLE

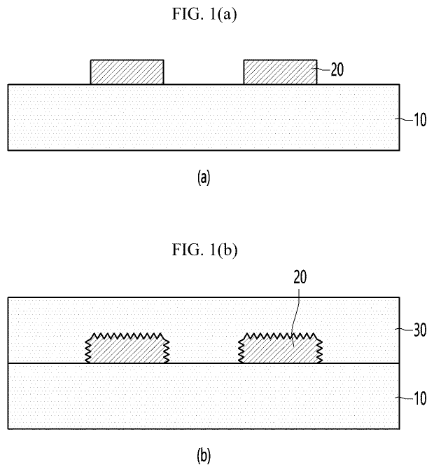

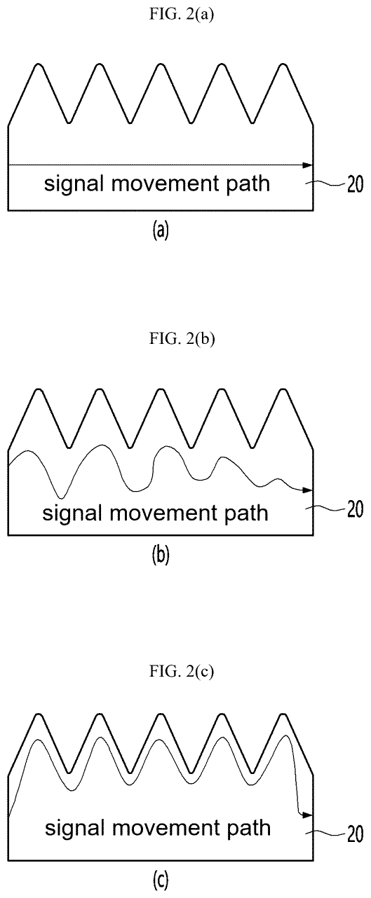

FIG. 1 is a cross-sectional view showing a circuit board according to a comparative example, and FIG. 2 is a view for explaining a signal transmission flow according to frequencies.

Referring to (a) of FIG. 1, the circuit board of the comparative example includes a first insulating layer 10 and a first circuit layer 20 disposed on the first insulating layer 10.

In addition, referring to (b) of FIG. 1, the circuit board of the comparative example includes a second insulating layer 30 disposed on the first circuit layer 20 for application of a multilayer structure.

At this time, in order to increase a bonding strength between the first circuit layer 20 and the second insulating layer 30, a certain level of roughness is applied to a surface of the first circuit layer 20. For example, a roughness (Ra) of about 1.0 um is applied to a surface of the first circuit layer 20. Through this, the comparative example improves the bonding strength between the first circuit layer 20 and the second insulating layer 30. However, if the roughness (Ra) of the surface of the first circuit layer 20 is 1.0 um or more, signal transmission loss increases as the frequency band increases.

Specifically, as an usage frequency of an application to which the circuit board is applied increases, the signal flow moves to a surface of a conductor (circuit layer) due to the skin effect.

That is, as in (a) of FIG. 2, in a first frequency range (e.g., 0 to 3 GHZ), the signal flows in a region away from the surface of the conductor. In addition, as in (b) of FIG. 2, in a second frequency range (e.g., 3 to 7 GHZ), the signal flows in a region adjacent to the surface of the conductor. Furthermore, as in (c) of FIG. 2, in a third frequency range (e.g., 10 GHz or higher), the signal flows along the surface of the conductor.

Therefore, if the roughness (Ra) of the surface of the first circuit layer 20 exceeds 1.0 um, the signal transmission loss increases in the high-frequency band. This makes it difficult to apply to applications using high frequencies.

Therefore, the comparative example minimizes signal transmission loss in a high-frequency band by applying a roughness (Ra) of 0.9 um or less to the surface of the first circuit layer 20. However, if the roughness (Ra) of the surface of the first circuit layer 20 decreases to 0.9 um or less, a bonding strength between the first circuit layer 20 and the second insulating layer 30 decreases. As a result, a problem occurs in which the second insulating layer 30 is peeled off from the first circuit layer 20.

Meanwhile, recently, a surface treatment technique has been provided that can minimize signal transmission loss by reducing the surface roughness of the first circuit layer 20 while also improving the bonding strength with the second insulating layer 30.

For example, the comparative example forms a copper oxide layer by oxidizing the surface of the first circuit layer 20. As a result, a roughness corresponding to the copper oxide layer is applied to the surface of the first circuit layer 20. In addition, in the comparative example, the copper oxide layer is reduced back to an original copper while the corresponding roughness is applied to the copper oxide layer.

At this time, an adhesion between the copper constituting the first circuit layer 20 and the copper oxide layer is low. As a result, a problem occurs in which the copper oxide layer separates from some of the surface of the first circuit layer 20. Therefore, a problem occurs in which a certain level of roughness is not applied to some of the surface of the first circuit layer 20.

In addition, in the comparative example, in a process of reducing the copper oxide layer back to copper, a problem occurs in which some of the copper oxide layers are not reduced back to copper. As a result, there is a problem in which the electrical characteristics of the first circuit layer 20 are deteriorated. In addition, in a case of the first circuit layer 20 of the comparative example, a content of hydroxyl groups (OH) on the surface is low, and thus there is a limit to improving the bonding strength with the second insulating layer 30.

Therefore, the embodiment provides a novel surface treatment technique capable of minimizing signal transmission loss by lowering a surface roughness of the circuit layer while maintaining the electrical characteristics of the circuit layer, and further improving the bonding strength or adhesion with the insulating layer.

### —Electronic Device—

Before describing an embodiment, an electronic device including the semiconductor package of the embodiment will be briefly described. The electronic device includes a main board (not shown). The main board may be physically and/or electrically connected to various components. For example, the main board may be electrically connected to the semiconductor package of the embodiment. Various devices may be mounted on the semiconductor package.

Memory chips such as volatile memory (e.g., DRAM), non-volatile memory (e.g., ROM), and flash memory, application processor chips such as a central processor (e.g., CPU), graphics processor (e.g., GPU), antenna chip, digital signal processor, cryptographic processor, microprocessor, and microcontroller, and logic chips such as analog-digital converters and ASICs (application-specific ICs) can be mounted in the semiconductor package.

For example, at least one of various types of passive devices and active devices may be mounted in the semiconductor package.

In this case, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Hereinafter, a circuit board and a semiconductor package according to an embodiment will be described in detail. Here, the circuit board may refer to a substrate before an electronic device is mounted. In addition, the semiconductor package may refer to a package in which an electronic device is mounted on the circuit board.

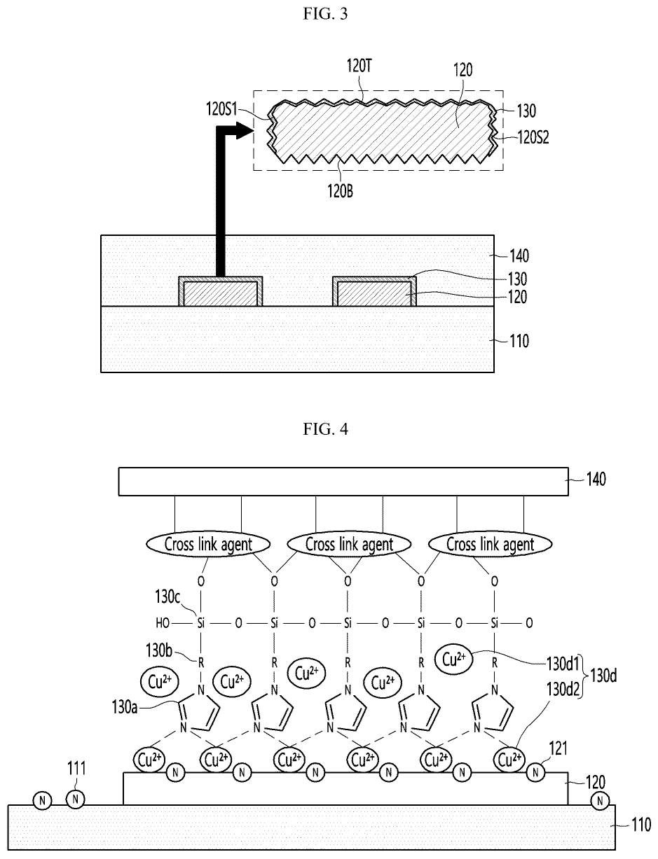

FIG. 3 is a cross-sectional view showing a circuit board according to a first embodiment, and FIG. 4 is a views for explaining a bonding relationship between a circuit layer, a buffer layer, and a second insulating layer according to an embodiment.

Referring to FIGS. 3 and 4, the circuit board may include an insulating layer and a circuit layer.

The insulating layer may include a first insulating layer 110 and a second insulating layer 140.

The first insulating layer 110 and the second insulating layer 140 may include a prepreg (PPG). The prepreg may be formed by impregnating an epoxy resin or the like into a fiber layer in the form of a fabric sheet, such as a glass fabric woven with glass fiber yarn, and then performing heat compression. However, the embodiment is not limited thereto, and the prepreg constituting at least one of the first insulating layer 110 and the second insulating layer 140 may include a fiber layer in the form of a fabric sheet woven with carbon fiber yarn.

In addition, at least one of the first insulating layer 110 and the second insulating layer 140 may be rigid or flexible.

At least one of the first insulating layer 110 and the second insulating layer 140 may have a thickness in a range of 10 um to 60 um. Preferably, at least one of the first insulating layer 110 and the second insulating layer 140 may have a thickness in a range of 12 um to 50 um. More preferably, at least one of the first insulating layer 110 and the second insulating layer 140 may have a thickness in a range of 15 um to 40 um.

If the thickness of at least one of the first insulating layer 110 and the second insulating layer 140 is less than 10 um, the circuit layer 120 included in the circuit board may not be stably protected. If the thickness of at least one of the first insulating layer 110 and the second insulating layer 140 exceeds 60 um, the thickness of the circuit board, the semiconductor package, and the electronic device including the same may increase. In addition, if at least one of the first insulating layer 110 and the second insulating layer 140 has a thickness exceeding 60 um, the thickness of the circuit layer 120 and the thickness of the through electrode (not shown) may increase accordingly. In addition, if the thickness of the circuit layer 120 and the thickness of the through electrode increase, signal transmission loss may increase.

A circuit layer 120 may be disposed on a surface of the insulating layer.

The circuit layer 120 may be disposed on the surface of the first insulating layer 110 for signal transmission in the circuit board. For example, the circuit layer 120 may be disposed on an upper surface of the first insulating layer 110.

That is, FIG. 3 may show one region in a multilayer structure of the circuit board of the embodiment. For example, FIG. 3 may show an insulating layer region disposed above and below the circuit layer 120 based on the circuit layer 120.

For example, the circuit layer 120 may have a thickness of 10 um to 30 um. Preferably, the circuit layer 120 may have a thickness of 12 um to 28 um. More preferably, the circuit layer 120 may have a thickness of 15 um to 27 um.

The circuit layer 120 may include a conductive material. For example, the circuit layer 120 may include at least one metal material selected from gold (Au), silver (Ag), platinum (Pt), titanium (Ti), tin (Sn), copper (Cu), and zinc (Zn). Preferably, the circuit layer 120 may be formed of copper (Cu) which has high electrical conductivity and is relatively inexpensive.

The circuit layer above (120) can be made using a conventional circuit board manufacturing process, an additive process, a subtractive process, a MSAP (Modified Semi Additive Process), and a SAP (Semi Additive Process) method, and detailed description is omitted here.

Although not shown in the drawing, the circuit layer 120 may include a nitride layer. For example, a nitride layer may be formed on a surface of the circuit layer 120 that does not contact the first insulating layer 110. Preferably, the circuit layer 120 is formed of copper, and the nitride layer may be a copper nitride layer.

The circuit layer 120 includes a plurality of surfaces.

The circuit layer 120 may include an upper surface 120T, a lower surface 120B, a first side surface 120S1, and a second side surface 120S2.

In addition, the lower surface 120B of the circuit layer 120 is a surface that contacts the first insulating layer 110.

At this time, the nitride layer may be formed after the circuit layer 120 is formed on the first insulating layer 110. For example, the nitride layer may be formed on the surface of the circuit layer 120 before the second insulating layer 140 is laminated.

Therefore, the nitride layer may be formed on a surface of the circuit layer 120 that does not contact the first insulating layer 110. Preferably, the nitride layer may be formed at the upper surface 120T, the first side surface 120S1, and/or the second side surface 120S2 of the circuit layer 120. The nitride layer may also be referred to as a surface layer of the upper surface 120T, the first side surface 120S1, and/or the second side surface 120S2 of the circuit layer 120.

Therefore, the upper surface 120T, the first side surface 120S1, and/or the second side surface 120S2 of the circuit layer 120 may contain nitrogen (N). The nitrogen (N) may be a functional group bonded to the buffer layer 130 in the surface layer of the circuit layer 120.

The nitride layer may be formed by plasma-treating the upper surface 120T, the first side surface 120S1, and/or the second side surface 120S2 of the circuit layer 120.

For example, the nitride layer may be formed by plasma treating the upper surface 120T, the first side surface 120S1, and/or the second side surface 120S2 of the circuit layer 120 using N₂ or NH₃.

At this time, when the circuit layer 120 is plasma treated using N₂, a plasma treatment agent may further include H₂. When the circuit layer 120 is plasma treated using N₂ and H₂, a ratio of the N₂ and H₂ may range from 1:3 to 3:1.

In an embodiment, in a process of manufacturing the circuit board, the surface of the circuit layer 120 is plasma treated before the second insulating layer 140 is laminated. Accordingly, a nitride layer having an atomic thickness may be formed on the surface of the circuit layer 120.

At this time, a reaction formula for forming the nitride layer is as follows.

### [Reaction Formula]

$${N}_{2} + {e}^{-} \to 2 N + {e}^{-}$$

$$3 {Cu}^{+} + {N}^{3 -} + {e}^{-} \to {C}_{3} N$$

$$4 {Cu}^{+} + {N}^{3 -} + {e}^{-} \to {C}_{3} N + Cu$$

Accordingly, the nitride layer formed on the surface of the circuit layer 120 may have the form of Cu₃N or Cu₃N₂ or Cu₄N.

At this time, in the comparative example, roughness is applied to the surface of the circuit layer through chemical etching before the second insulating layer is laminated. However, when the circuit layer is applied with chemical etching, the roughness (Ra) of the circuit layer exceeds 1.0 um. In addition, when the roughness (Ra) of the circuit layer exceeds 1.0 um, signal transmission loss may increase when transmitting a signal in a high-frequency band. In addition, when a certain level of roughness (Ra) is not applied to the circuit layer, it is difficult to secure bonding strength or adhesion between the circuit layer and the second insulating layer.

At this time, in the embodiment, a process of applying roughness by performing an additional process on the circuit layer 120 is not performed. Accordingly, in the embodiment, the surface of the circuit layer 120 may have a fine roughness. For example, the surface of the circuit layer 120 of the embodiment has a roughness (Ra) corresponding to the nitride layer formed through the plasma treatment.

Here, as described above, the nitride layer formed through the plasma treatment is selectively applied to the surface of the circuit layer 120. For example, the nitride layer is formed on the upper surface 120T, the first side surface 120S1, and the second side surface 120S2 of the circuit layer 120 excluding the lower surface 120B. Accordingly, the surface of the circuit layer 120 of the embodiment can have different roughnesses (Ra) for each region.

The upper surface 120T, the first side surface 120S1, and the second side surface 120S2 of the circuit layer 120 can have roughnesses (Ra) corresponding to each other. Here, the meaning of having roughness corresponding to each other may mean that a roughness deviation in the upper surface 120S2, the first side surface 120S1, and the second side surface 120S2 of the circuit layer 120 is 50% or less, 40% or less, 30% or less, 15% or less, 10% or less, or 5% or less.

The roughness (Ra) of the upper surface 120T, the first side surface 120S1, and the second side surface 120S2 of the circuit layer 120 may have a range of 0.1 um to 0.9 um. Preferably, the roughness (Ra) of the upper surface 120T, the first side surface 120S1, and the second side surface 120S2 of the circuit layer 120 may have a range of 0.1 um to 0.7 um. More preferably, the roughness (Ra) of the upper surface 120T, the first side surface 120S1, and the second side surface 120S2 of the circuit layer 120 may have a range of 0.1 um to 0.5 um. This can be achieved by not performing a process of imparting roughness through etching the upper surface 120T, the first side surface 120S1, and the second side surface 120S2 of the circuit layer 120.

If the roughness (Ra) of the upper surface 120T, the first side surface 120S1, and the second side surface 120S2 of the circuit layer 120 is less than 0.1 um, the bonding strength or adhesion with the second insulating layer 140 may be affected. If the roughness (Ra) of the upper surface 120T, the first side surface 120S1, and the second side surface 120S2 of the circuit layer 120 is less than 0.1 um, it may affect the bonding strength or adhesion with the buffer layer 130 disposed on the surface of the circuit layer 120.

In addition, if the roughness (Ra) of the upper surface 120T, the first side surface 120S1, and the second side surface 120S2 of the circuit layer 120 exceeds 0.9 um, the transmission loss of the signal transmitted through the circuit layer 120 may increase. For example, if the roughness (Ra) of the upper surface 120T, the first side surface 120S1, and the second side surface 120S2 of the circuit layer 120 exceeds 0.9 um, it may be difficult to use in a product that transmits a high-frequency band signal.

Meanwhile, the roughness (Ra) of the lower surface 120B of the circuit layer 120 may be different from the roughness (Ra) of the upper surface 120T, the first side surface 120S1 and/or the second side surface 120S2 of the circuit layer 120. Preferably, the roughness (Ra) of the lower surface 120B of the circuit layer 120 may be greater than the roughness (Ra) of the upper surface 120T, the first side surface 120S1 and/or the second side surface 120S2 of the circuit layer 120.

The roughness (Ra) of the lower surface 120B of the circuit layer 120 may have a range of 0.6 um to 0.9 um. Preferably, the roughness (Ra) of the lower surface 120B of the circuit layer 120 may have a range of 0.65 um to 0.9 um. More preferably, the roughness (Ra) of the lower surface 120B of the circuit layer 120 may have a range of 0.7 um to 0.9 um.

If the roughness (Ra) of the lower surface 120B of the circuit layer 120 is less than 0.6 um, the adhesion or bonding force between the circuit layer 120 and the first insulating layer 110 may be reduced. Accordingly, a problem in which the circuit layer 120 is peeled off from the first insulating layer 110 may occur.

In addition, if the roughness (Ra) of the lower surface 120B of the circuit layer 120 exceeds 0.9 um, the transmission loss of the signal transmitted through the circuit layer 120 increases, and thus, it may be difficult to apply to a product using a high-frequency band.

Meanwhile, the plasma treatment is performed on an entire exposed surface while the circuit layer 120 is disposed on the first insulating layer 110.

Accordingly, an upper surface of the first insulating layer 110 where the circuit layer 120 is not disposed can also be subjected to plasma treatment. For example, the upper surface of the first insulating layer 110 can include nitrogen (N).

In conclusion, the embodiment performs plasma treatment using nitrogen (N) on the surface of the circuit layer 120 and the surface of the first insulating layer 110, so that a first functional group (e.g., a nitride group) containing nitrogen (N) is formed on the surfaces of the circuit layer 120 and the first insulating layer 110.

The embodiment forms a nitride layer containing nitrogen (N) on the surface of the circuit layer 120. Accordingly, the embodiment can improve the adhesion or bonding force between the circuit layer 120 and the second insulating layer 140 without providing a certain level of roughness to the surface of the circuit layer 120. This can be achieved by a buffer layer 130 disposed on the circuit layer 120.

The buffer layer 130 can be selectively formed on the surface of the circuit layer 120. Preferably, the buffer layer 130 can be formed on a surface of the circuit layer 120 that does not contact the first insulating layer 110. Specifically, the buffer layer 130 can be formed on the upper surface 120T, the first side surface 120S1, and/or the second side surface 120S2 of the circuit layer 120.

The buffer layer 130 may have a certain level of roughness. At this time, the buffer layer 130 is formed on the surface of the circuit layer 120 in a thin film form. Accordingly, the roughness (Ra) of the buffer layer 130 may correspond to the roughness (Ra) of the circuit layer 120. Specifically, the roughness (Ra) of the buffer layer 130 may correspond to the roughness (Ra) of any one of the surfaces of the upper surface 120T, the first side surface 120S1, and the second side surface 120S2 of the circuit layer 120.

The buffer layer 130 may have a thickness in a range of 10 nm to 50 nm. Preferably, the buffer layer 130 may have a thickness in a range of 12 nm to 48 nm. More preferably, the buffer layer 130 may have a thickness in a range of 15 nm to 45 nm.

If the thickness of the buffer layer 130 is less than 10 nm, the effect achieved by the buffer layer 130 may be insufficient because the thickness of the buffer layer 130 is too thin. For example, if the thickness of the buffer layer 130 is less than 10 nm, the adhesion or bonding force between the circuit layer 120 and the second insulating layer 140 may not be secured.

In addition, if the thickness of the buffer layer 130 exceeds 50 nm, a process time for forming the buffer layer 130 may increase, and a process cost may increase. In addition, if the thickness of the buffer layer 130 exceeds 50 nm, the adhesion may not increase as much as the thickness of the buffer layer 130 increases. For example, when the thickness of the buffer layer 130 exceeds 50 nm, the adhesion between the circuit layer 120 and the second insulating layer 140 may be similar to the adhesion between the circuit layer 120 and the second insulating layer 140 when the thickness of the buffer layer 130 is less than 50 nm. In addition, when the thickness of the buffer layer 130 exceeds 50 nm, a dielectric constant of the first insulating layer 110 or the second insulating layer 140 may be affected, and thus, this may make it difficult to apply to products that use high-frequency bands.

The buffer layer 130 may include a plurality of elements.

The plurality of elements included in the buffer layer 130 are included in a form of molecules or ions boned to each other within the buffer layer 130, and the molecules, the molecules, and the molecules and the ions may be chemically bonded to each other to form the buffer layer 130.

The buffer layer 130 may include a plurality of functional groups. For example, the buffer layer 130 may include a first functional group and a second functional group. The first functional group may have a function of increasing the adhesion between the buffer layer 130 and the circuit layer 120. In addition, the second functional group may have a function of increasing the adhesion between the buffer layer 130 and the second insulating layer 140. In conclusion, the first functional group and the second functional group of the buffer layer 130 may have a function of increasing the adhesion between the circuit layer 120 and the second insulating layer 140.

The buffer layer 130 may include at least one of a copper element, a silicon element, an oxygen element, a hydrogen element, a carbon element, a sulfur element, and a nitrogen element. In the buffer layer 130, the copper element, the oxygen element, the hydrogen element, the carbon element, the silicon element, the sulfur element, and the nitrogen element may be bonded to each other to exist in the form of molecules or may exist in the form of individual ions.

Some of the plurality of elements included in the buffer layer 130 may correspond to the first functional group of the buffer layer 130 to bonded to the circuit layer 120. For example, the copper element and the nitrogen element included in the buffer layer 130 may correspond to the first functional group of the buffer layer 130 to bonded to the circuit layer 120. For example, the first functional group of the buffer layer 130 may chemically bond to the circuit layer 120.

In addition, other parts of the plurality of elements included in the buffer layer 130 may correspond to a second functional group of the buffer layer 130 bonded to the second insulating layer 140. The second functional group included in the buffer layer 130 may be chemically bond to the second insulating layer 140.

Meanwhile, the molecules included in the buffer layer 130 may include at least two types of molecules depending on a size or molecular weight of the molecules. For example, the molecules may include macromolecules and unimolecular molecules. For example, the macromolecules, unimolecular molecules, and metal ions within the buffer layer 130 may have a structure in which they are chemically bonded to each other by covalent bonds and coordination bonds within the buffer layer 130.

The buffer layer 130 will be described in detail.

The buffer layer 130 includes a first functional group and a second functional group. The first functional group and the second functional group may be defined as terminal groups of the buffer layer 130 that are connected to any one of the macromolecules, unimolecular molecules, or metal ions that constitute the buffer layer 130.

The buffer layer 130 may be formed of an organic silane agent containing an azole group. Preferably, the buffer layer 130 may be formed of a solution in which copper ions are added to an organic silane agent containing an azole group. The copper ions may mean Cu₂+ or Cu+, but are not limited thereto.

Accordingly, the buffer layer 130 may have a structure as shown in a chemical formula 1 below.

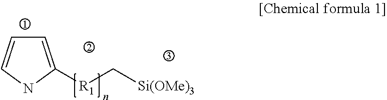

In the chemical formula 1, number 1 may correspond to the first functional group of the buffer layer 130. That is, the buffer layer 130 may include a first functional group containing nitrogen. For example, the first functional group may include at least one azole group among diazole, triazole, tetra azole, benzo triazole, benzo thiazole, and nitro triazole.

The first functional group may enhance the adhesion between the buffer layer 130 and the circuit layer 120 while enhancing the cohesion of the buffer layer 130.

For example, the first functional group of the buffer layer 130 may chemically bond with the circuit layer 120. Preferably, the first functional group of the buffer layer 130 may coordinately bond with nitrogen (N) of the nitride layer of the circuit layer 120.

In addition, the first functional group can coordinately bond with the metal ion included in the buffer layer 130. For example, the buffer layer 130 includes a copper ion. In addition, the first functional group can coordinately bond with the copper ion.

In this case, when the first functional group is used to coordinately bond with nitrogen (N) of the circuit layer 120, the adhesion between the circuit layer 120 and the buffer layer 130 can be secured, but an internal cohesion of the buffer layer 130 can be reduced. In addition, when the internal cohesion of the buffer layer 130 is reduced, a peeling problem in the buffer layer 130 can occur. Therefore, the embodiment allows the buffer layer 130 to include a copper ion, which is a metal ion, and allows the copper ion to be coordinately bonded with the first functional group, thereby improving the adhesion between the buffer layer 130 and the circuit layer 120 and also improving the internal cohesion of the buffer layer 130.

At this time, the copper ion of the buffer layer 130 can form a polymer network by bonding with the first functional group. This can be expressed by a chemical formula 2 below.

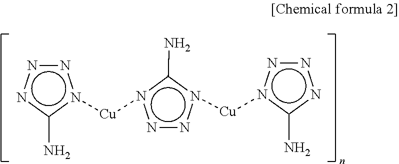

In addition, the copper ions included in the buffer layer 130 can be bonded to the circuit layer 120. Preferably, the copper ions included in the buffer layer 130 can be bonded to the nitride layer of the circuit layer 120. More preferably, the copper ions included in the buffer layer 130 can be coordinately bonded to a nitride group including nitrogen (N) corresponding to the nitride layer of the circuit layer 120.

That is, the embodiment allows the first functional group of the buffer layer 130 to be coordinately bonded to the nitride layer of the circuit layer 120, and further allows the copper ions of the buffer layer 130 to be coordinately bonded to the nitride layer of the circuit layer 120. Accordingly, the embodiment can improve the internal cohesion of the buffer layer 130 and further improve the adhesion between the buffer layer 130 and the circuit layer 120.

In the chemical formula 1, number 3 may correspond to the second functional group of the buffer layer 130. Preferably, the buffer layer 130 may include a second functional group that chemically bonds with the second insulating layer 140. In addition, the second functional group may include a siloxane group.

At this time, the siloxane group in the first embodiment may include methyl as in chemical formula 1. For example, the second functional group in the first embodiment may be Si(OMe)₃. For example, the second functional group in the first embodiment may be a trimethyl siloxane group or a triethyl siloxane group.

However, the second functional group of the embodiment is not limited thereto. For example, the second functional group of the buffer layer 130 may be a siloxane group including OH— as shown in FIG. 4.

In addition, number 2 in the chemical formula 1 may correspond to an alkyl group (R) included in the buffer layer 130. ‘n’ of the alkyl group (R) in the chemical formula 1 may be 3 to 5. The alkyl group (R) may have an alkyl chain or an aromatic ring form. For example, the alkyl group (R) may have an alkyl chain form containing sulfur or nitrogen.

Referring to FIG. 4, the bonding relationship between the circuit layer 120, the buffer layer 130, and the second insulating layer 140 of the embodiment will be described.

A nitride layer is formed on the surface of the circuit layer 120. For example, a functional group 121 containing nitrogen (N) is formed on the surface of the circuit layer 120.

At this time, as described above, the plasma treatment may be performed not only on the surface of the circuit layer 120 but also on the upper surface of the first insulating layer 110. In addition, a functional group 111 containing nitrogen (N) may be formed on the upper surface of the first insulating layer 110. In addition, the functional group 111 of the first insulating layer 110 may be bonded to a functional group included in the second insulating layer 140. For example, the functional group 111 of the first insulating layer 110 may be covalently bonded to a functional group such as —NH or —OH of the second insulating layer 140. Accordingly, the embodiment may secure not only the adhesion between the circuit layer 120 and the second insulating layer 140, but also the adhesion between the first insulating layer 110 and the second insulating layer 140. That is, the functional group 111 of the first insulating layer 110 may be a chemical functional group containing nitrogen such as —NH₂, ═NH, ≡NO₂, etc.

In addition, the buffer layer 130 may include a first functional group 130a. The first functional group 130a may be an azole group including nitrogen (N). The first functional group 130a may be coordinately bonded with the functional group 121 of the circuit layer 120. As a result, the adhesion between the buffer layer 130 and the circuit layer 120 may be improved.

In addition, the buffer layer 130 includes an alkyl group 130b. The alkyl group 130b may be bonded between the first functional group 130a and the second functional group 130c.

The buffer layer 130 may include a second functional group 130c. The second functional group 130c may be a siloxane group. For example, the second functional group 130c may include an —OH group.

In addition, the second functional group 130c can covalently bond with a functional group such as —NH group or —OH of the second insulating layer 140. By this, the adhesion between the buffer layer 130 and the second insulating layer 140, and further, the adhesion between the circuit layer 120 and the second insulating layer 140 can be improved.

The buffer layer 130 includes a copper ion 130d. The copper ion 130d includes a first ion group 130d1 that exists alone in the buffer layer 130. In addition, the copper ion 130d can include a second ion group 130d2 that coordinately bonds with either the first functional group 130a of the buffer layer 130 or the functional group 121 of the circuit layer 120.

The embodiment can improve the reliability of the circuit board.

Preferably, the embodiment can improve the electrical reliability and physical reliability of the circuit board.

To this end, the embodiment forms a functional group including nitrogen on a surface of a circuit layer disposed on a first insulating layer. For example, the embodiment forms a nitride layer by plasma-treating the surface of the circuit layer. In addition, the embodiment forms a buffer layer on the nitride layer of the circuit layer.

The buffer layer includes a first functional group bonded to the circuit layer and a second functional group bonded to a second insulating layer disposed on the circuit layer. The first functional group may be an azole group. The first functional group may be coordinately bonded with a functional group including nitrogen (N) formed on the surface of the circuit layer. In addition, the second functional group may be covalently bonded with a functional group included in the second insulating layer. To this end, the buffer layer may be formed of an organic silane agent including an azole group.

Through this, the embodiment can improve an adhesion between the circuit layer and the second insulating layer by using the buffer layer. Through this, the embodiment can solve a physical reliability problem in which the second insulating layer is peeled off from the circuit layer.

At this time, the embodiment also performs plasma treatment on an upper surface of the first insulating layer during plasma treatment of the circuit layer. Accordingly, a functional group including nitrogen (N) can be formed on the upper surface of the first insulating layer. In addition, the functional group formed on the upper surface of the first insulating layer can be shared with the functional group of the second insulating layer. Accordingly, the embodiment can improve not only the adhesion between the circuit layer and the second insulating layer, but also the adhesion between the first insulating layer and the second insulating layer.

In addition, the buffer layer of the embodiment includes a metal ion. Preferably, the buffer layer includes a copper ion. At this time, the copper ion can coordinately bond with the functional group including nitrogen (N) of the circuit layer. Through this, the embodiment can further improve the adhesion between the buffer layer and the circuit layer.

Furthermore, the copper ion included in the buffer layer can coordinately bond with the first functional group of the buffer layer. Through this, the embodiment can strengthen an internal cohesion of the buffer layer through the coordination bond between the first functional group and the copper ion. Accordingly, the embodiment can further improve the adhesion between the circuit layer and the second insulating layer.

Meanwhile, the embodiment secures the adhesion between the circuit layer and the second insulating layer by using the functional group of the circuit layer and the first and second functional groups of the buffer layer. By this, the embodiment does not require an additional roughness imparting process for securing the adhesion to the circuit layer. Accordingly, the embodiment can prevent deformation of the circuit layer, and further improve the electrical characteristics of the circuit layer.

In addition, the embodiment can make a surface of the circuit layer have a fine roughness. This can be achieved by lowering the roughness of the surface of the circuit layer by securing the adhesion using the buffer layer. By this, the circuit layer of the embodiment can satisfy a surface roughness (Ra) of 0.1 um to 0.9 um. Accordingly, the embodiment can minimize transmission loss of a signal transmitted through the circuit layer. Furthermore, the embodiment can provide a circuit board applicable to a product using a high-frequency band.

Meanwhile, the embodiment can improve the adhesion between the circuit layer 120 and the second insulating layer 140 while the surface roughness (Ra) of the circuit layer 120 has a fine roughness.

Preferably, the adhesion (90° Peel Strength) between the circuit layer 120 and the second insulating layer 140 of the embodiment can have a range of 0.55 to 1.5 kgf/cm.

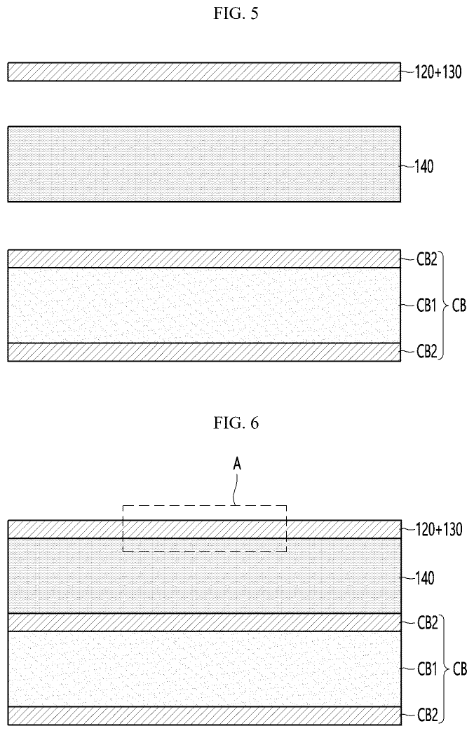

The adhesion (90° Peel Strength) can be measured by the following method. FIGS. 5 and 6 are views for explaining a method for measuring the adhesion (90° Peel Strength) of a circuit board according to the embodiment.

Referring to FIG. 5, the embodiment prepares a basic material for testing the adhesion (90° Peel Strength). For example, the embodiment prepares a carrier board CB. The carrier board CB may be CCL. For example, the carrier board CB may include a carrier insulating layer CB1 and a carrier copper layer CB2 disposed on both sides of the carrier insulating layer CB1.

Thereafter, the embodiment places a second insulating layer 140 on the carrier board CB, and attaches a circuit layer 120 on which a buffer layer 130 according to the embodiment is formed on the second insulating layer 140.

Next, referring to FIG. 6, the embodiment performs a 90° Peel Strength test on a region (A) of the circuit layer 120 including the buffer layer 130.

The 90° Peel Strength test may be performed in a following order.
(1) The adhesion (90° Peel Strength) test is performed by bonding a circuit layer 120 formed with a buffer layer 130 together with a second insulating layer 140 on a carrier board CB,
(2) Forming a sheath in a region (e.g., a 1 cm wide region) of the circuit layer 120,
(3) Measuring a resistance-peel strength when the region where the sheath is formed is separated by applying force at 90°.

The adhesion (90° Peel Strength) test can follow international standard criteria for evaluation methods such as ASTM-D6862.

In addition, the adhesion (90° Peel Strength) between the circuit layer 120 and the second insulating layer 140 of the embodiment tested in this way can have a range of 0.55 to 1.5 kgf/cm.

Furthermore, the embodiment can also improve the adhesion between the first insulating layer 110 and the second insulating layer 140. At this time, the adhesion between the first insulating layer 110 and the second insulating layer 140 can be conducted through a thermal reliability test such as IR reflow or solder dup.

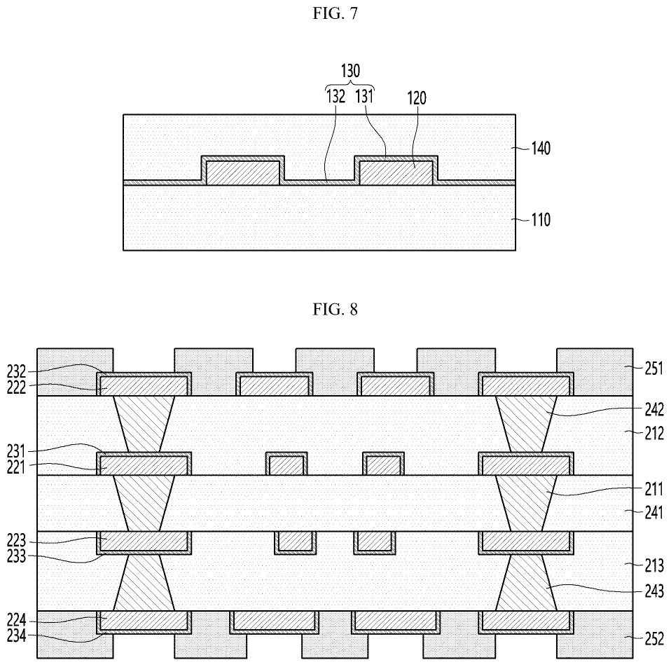

FIG. 7 is a cross-sectional view showing a circuit board according to the second embodiment.

Referring to FIG. 7, the circuit board includes a first insulating layer 110.

In addition, a circuit layer 120 is disposed on the first insulating layer 110.

In addition, a buffer layer 130 is disposed on upper surfaces of the first insulating layer 110 and the circuit layer 120.

In addition, a second insulating layer 140 is disposed on the buffer layer 130.

According to the second embodiment, the buffer layer 130 is divided into a plurality of parts.

That is, the buffer layer 130 of the first embodiment is formed only on the upper surface 120T, the first side surface 120S1, and the second side surface 120S2 of the circuit layer 120.

Unlike this, the buffer layer 130 of the second embodiment may include a first portion 131 formed on the circuit layer 120 and a second portion 132 disposed on the upper surface of the first insulating layer 110.

The first portion 131 of the buffer layer 130 may be disposed on the upper surface 120T, the first side surface 120S1, and the second side surface 120S2 of the circuit layer 120. In addition, the first portion 131 of the buffer layer 130 may improve the adhesion between the circuit layer 120 and the second insulating layer 140.

The second portion 132 of the buffer layer 130 may be disposed in a region of the upper surface of the first insulating layer 110 where the circuit layer 120 is not disposed. The second portion 132 of the buffer layer 130 may improve the adhesion between the first insulating layer 110 and the second insulating layer 140. However, the organic silane agent for forming the buffer layer 130 has a higher reactivity with the circuit layer 120 than with the first insulating layer 110. Accordingly, the buffer layer 130 may be formed while being concentrated on the circuit layer 120. However, in the second embodiment, the second portion 132 of the buffer layer 130 may be formed on at least a portion of the upper surface of the first insulating layer 110.

That is, although FIG. 7 illustrates that the second portion 132 of the buffer layer 130 is formed entirely on the upper surface of the insulating layer 110, the embodiment is not limited thereto. Preferably, the second portion 132 of the buffer layer 130 may be partially formed in the upper surface region of the first insulating layer 110 where the circuit layer 120 is not disposed.

FIG. 8 is a cross-sectional view showing a circuit board according to a third embodiment.

Referring to FIG. 8, the circuit board of the third embodiment may have a multilayer structure.

For example, the circuit board includes an insulating layer.

The insulating layer includes a first insulating layer 211, a second insulating layer 212, and a third insulating layer 213. At this time, the circuit board is illustrated as having a three-layer structure based on a number of insulating layers in the drawing, but is not limited thereto. For example, the circuit board may have four or more layers based on the number of insulating layers.

The first insulating layer 211 may be an inner insulating layer located at an inner side of the circuit board.

In addition, the second insulating layer 212 and the third insulating layer 213 may be outer insulating layers located at an outer side of the circuit board. In addition, when the circuit board has four or more layers based on the number of insulating layers, the inner insulating layer may include a plurality of first insulating layers.

The circuit board includes a circuit layer.

Specifically, the circuit layer includes a first circuit layer 221 disposed on an upper surface of the first insulating layer 211. In addition, the circuit layer includes a second circuit layer 222 disposed on an upper surface of the second insulating layer 212. In addition, the circuit layer includes a third circuit layer 223 disposed on a lower surface of the first insulating layer 211. In addition, the circuit layer includes a fourth circuit layer 224 disposed on a lower surface of the third insulating layer 213.

The first circuit layer 221 and the third circuit layer 223 may be inner circuit layers located at an inner side of the circuit board. In addition, the second circuit layer 222 and the fourth circuit layer 224 may be outer circuit layers located at an outer side of the circuit board.

The circuit board includes a buffer layer. Preferably, the circuit board of the embodiment includes a buffer layer disposed on each circuit layer.

A first buffer layer 231 is formed on the first circuit layer 221. The first buffer layer 231 may be formed to surround the upper surface and side surfaces of the first circuit layer 221. The first buffer layer 231 may improve the adhesion between the first circuit layer 221 and the second insulating layer 212.

A second buffer layer 232 is formed on the second circuit layer 222. The second buffer layer 232 may be formed to surround the upper surface and side surfaces of the second circuit layer 222. The second buffer layer 232 may improve the adhesion between the second circuit layer 222 and the first protective layer 251. That is, the embodiment forms a buffer layer not only on the inner circuit layer but also on the outer circuit layer. Through this, the embodiment may improve the adhesion between the outer circuit layer and a protective layer.

A third buffer layer 233 is formed on the third circuit layer 223. The third buffer layer 233 may be formed to surround the lower surface and the side surface of the third circuit layer 223. The third buffer layer 233 may improve the adhesion between the third circuit layer 223 and the third insulating layer 213.

A fourth buffer layer 234 is formed on the fourth circuit layer 224. The fourth buffer layer 234 may be formed to surround the lower surface and the side surface of the fourth circuit layer 224. The fourth buffer layer 234 may improve the adhesion between the fourth circuit layer 224 and the second protective layer 252.

The circuit board includes a through electrode. The through electrode may penetrate at least one of a plurality of insulating layers.

The circuit board includes a first through electrode 241. The first through electrode 241 passes through the first insulating layer 211. The first through electrode 241 electrically connects the first circuit layer 221 and the third circuit layer 223. At this time, a side surface of the first through electrode 241 may have a roughness (Ra) different from the roughness (Ra) of the upper surface or side surface of the first circuit layer 221. That is, the upper surface or side surface of the first circuit layer 221 may have a fine roughness by securing adhesion through plasma treatment as described above. In contrast, a side surface of the first through electrode 241 may have a roughness (Ra) greater than the roughness (Ra) of the upper surface or side surface of the first circuit layer 221.

The circuit board includes the second through electrode 242. The second through electrode 242 passes through the second insulating layer 212. The second through electrode 242 electrically connects the first circuit layer 221 and the second circuit layer 222. A side surface of the second through electrode 242 may have a roughness (Ra) greater than the roughness (Ra) of the upper surface or the side surface of the second circuit layer 222. Meanwhile, in the drawing, the second through electrode 242 is illustrated as being disposed on the first buffer layer 231, but in reality, the first buffer layer 231 is not disposed on the first circuit layer 221 that vertically overlaps the second through electrode 242. Accordingly, the second through electrode 242 is in direct contact with the upper surface of the first circuit layer 221.

The circuit board includes a third through electrode 243. The third through electrode 243 passes through the third insulating layer 213. The third through electrode 243 electrically connects the third circuit layer 223 and the fourth circuit layer 224. The side surface of the fourth through electrode 234 may have a roughness (Ra) greater than the roughness (Ra) of the side surface or lower surface of the third circuit layer 223 and the roughness (Ra) of the side surface or lower surface of the fourth circuit layer 224. Meanwhile, in the drawing, the third through electrode 243 is depicted as being disposed on the third buffer layer 233, but in reality, the third buffer layer 233 is not disposed on the third circuit layer 223 that vertically overlaps the third through electrode 243. Accordingly, the third through electrode 243 is in direct contact with the upper surface of the third circuit layer 223.

The circuit board includes a protective layer. The protective layer protects the insulating layer and the surface of the circuit layer of the outer layer of the circuit board.

The protective layer includes a first protective layer 251 disposed on a second insulating layer 212. The first protective layer 251 can protect an upper surface of the second insulating layer 212 and an upper surface of the second circuit layer 222. The first protective layer 251 can include an opening (not shown) that overlaps at least a portion of the upper surface of the second circuit layer 222 in a thickness direction.

The protective layer includes a second protective layer 252 disposed on the third insulating layer 213. The second protective layer 252 can protect the lower surface of the third insulating layer 213 and the lower surface of the fourth circuit layer 224. The second protective layer 252 can include an opening (not shown) that overlaps at least a portion of the lower surface of the fourth circuit layer 224 in the thickness direction.

As described above, the circuit board of the third embodiment has a multilayer structure. In addition, a buffer layer is formed on each circuit layer included in the circuit board having a multilayer structure. Furthermore, the embodiment forms a buffer layer on the outermost circuit layer. Through this, the embodiment can improve the adhesion between the circuit layer and the protective layer.

Meanwhile, although it is illustrated in the drawing that a buffer layer is formed in a region that overlaps in the thickness direction with the openings of the first protective layer 251 and the second protective layer 252 among the surfaces of the second circuit layer 222 and the fourth circuit layer 224, but the embodiment is not limited thereto. For example, in the drawing, a buffer layer is not formed in a region that overlaps in the thickness direction with the openings of the first protective layer 251 and the second protective layer 252 among the surfaces of the second circuit layer 222 and the fourth circuit layer 224, thereby allowing a connection part for mounting a chip to be disposed.

Hereinafter, the layer structure of the circuit layer and the through electrode included in the circuit board of the embodiment will be described.

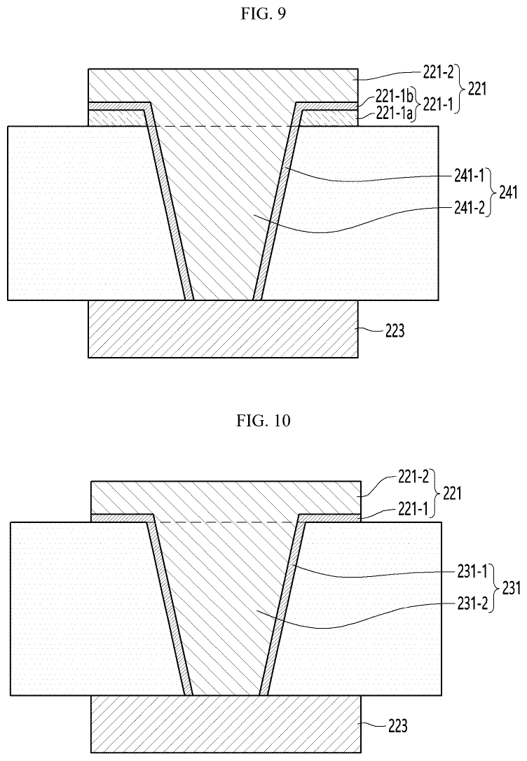

FIG. 9 is a cross-sectional view showing a layer structure of a circuit layer and a through electrode according to a first embodiment, and FIG. 10 is a cross-sectional view showing a layer structure of a circuit layer and an electrode according to a second embodiment.

Hereinafter, any one of the first circuit layer 221 to the fourth circuit layer 124 will be mainly described. For example, hereinafter, a layer structure of the first circuit layer 221 will be described. However, a layer structure of the second circuit layer 122, the third circuit layer 123, and the fourth circuit layer 124 may correspond to a layer structure of the first circuit layer 221 described below.

Accordingly, hereinafter, the first insulating layer 111 will be referred to as an insulating layer, the first circuit layer 221 will be referred to as a circuit layer, and the first through electrode 231 will be referred to as a through electrode.

Referring to FIG. 9, the circuit board of the first embodiment may be manufactured by a MSAP method.

In this case, the circuit layer may include a first layer and a second layer.

In addition, the first layer of the circuit layer may mean a first metal layer and a second metal layer to be described below. In addition, the second layer of the circuit layer may mean a third metal layer to be described below.

Hereinafter, the first to third metal layers of the circuit layer will be mainly described.

Meanwhile, the circuit board includes an insulating layer 211, a circuit layer 221, and a through electrode 231.

The circuit layer 221 may include a first metal layer 221-1 and a second metal layer 221-2.

The first metal layer 221-1 of the circuit layer 221 may be disposed on an upper surface of the insulating layer 211. The first metal layer 221-1 of the circuit layer 221 may mean a seed layer of the first metal layer 221-1.

In this case, the circuit layer 221 is manufactured by an MSAP process. Accordingly, the first metal layer 221-1 of the circuit layer 221 may be formed of a plurality of layers.

Preferably, the first metal layer 221-1 of the circuit layer 221 may include a first-first metal layer 221-1a and a first-second metal layer 221-1b.

The first-first metal layer 221-1a of the first metal layer 221-1 of the circuit layer 221 may be disposed on an upper surface of the insulating layer 111. The first-first metal layer 221-1a of the first metal layer 221-1 of the circuit layer 221 may mean a copper foil layer disposed on the upper surface of the insulating layer 111. For example, the first-first metal layer 221-1a of the first metal layer 221-1 of the circuit layer 221 may mean a copper foil. The first metal layer 221-1a of the first metal layer 221-1 of the circuit layer 221 may have a thickness in a range of 2 μm to 5 μm.

The first-second metal layer 221-1b of the first metal layer 221-1 of the circuit layer 221 may be disposed on the first-first metal layer 221-1a. For example, the first-second metal layer 221-1b of the first metal layer 221-1 of the circuit layer 221 may be formed on the first-first metal layer 221-1a by electroless plating. Preferably, the first-second metal layer 221-1b of the first metal layer 221-1 of the circuit layer 221 may be a chemical copper plating layer. The first-second metal layer 221-1b of the first metal layer 221-1 of the circuit layer 221 may have a thickness in a range of 0.2 μm to 2 μm.

The second metal layer 221-2 of the circuit layer 221 is disposed on the first metal layer 221-1 of the circuit layer 221. For example, the second metal layer 221-2 of the circuit layer 221 is disposed on the first-second metal layer 221-1b of the first metal layer 221-1 of the circuit layer 221. For example, the second metal layer 221-2 of the circuit layer 221 may be an electroplating layer formed by electroplating the first-second metal layer 221-1b with a seed layer. The second metal layer 221-2 of the circuit layer 221 may have a thickness in a range of 15 um to 30 um. At this time, the second metal layer 221-2 of the circuit layer 221 may be composed of a plurality of layers. For example, the second metal layer 221-2 of the circuit layer 221 may include a flash electrolytic copper plating layer and a pattern electrolytic copper plating layer, but is not limited thereto.

Meanwhile, the through electrode 231 may penetrate the insulating layer 211. For example, the through electrode 231 may be formed by filling an inside of the through hole penetrating the insulating layer 211 with a conductive material. In this case, the through electrode 231 may be formed simultaneously in a process of forming the circuit layer 221.

Preferably, the through electrode 231 includes a first metal layer 231-1 corresponding to the first metal layer 221-1 of the circuit layer 221. Preferably, the first metal layer 231-1 of the through electrode 231 may correspond to the first-second metal layer 221-1b of the first metal layer 221-1 of the circuit layer 221.

Specifically, the first-second metal layer 221-1b of the first metal layer 221-1 of the circuit layer 221 and the first metal layer 231-1 of the through electrode 231 may refer to one layer formed by a chemical copper plating process. However, the first-second metal layer 221-1b of the first metal layer 221-1 of the circuit layer 221 and the first metal layer 231-1 of the through electrode 231 may be classified according to an arrangement position of the chemical copper plating layer.

For example, in one chemical copper plating layer, the first-second metal layer 221-1b of the first metal layer 221-1 of the circuit layer 221 may refer to a portion of the circuit layer 221 in contact with the first-first metal layer 221-1a of the first metal layer 221-1.

For example, in one chemical copper plating layer, the first metal layer 231-1 of the through electrode 231 may refer to a portion in contact with an inner wall of a through hole penetrating the insulating layer 211.

Meanwhile, the through electrode 231 may include a second metal layer 231-2. The second metal layer 231-2 of the through electrode 231 may correspond to the second metal layer 221-2 of the circuit layer 221.

Preferably, the through electrode 231 includes a second metal layer 231-2 corresponding to the second metal layer 221-2 of the circuit layer 221. That is, the second metal layer 221-2 of the circuit layer 221 and the second metal layer 231-2 of the through electrode 231 may mean one layer formed by electroplating the chemical copper plating layer as a seed layer. However, the second metal layer 221-2 of the circuit layer 221 and the second metal layer 231-2 of the through electrode 231 may be classified according to an arrangement position of the electroplating layer.

For example, the second metal layer 231-2 of the through electrode 231 may refer to a portion of one electroplating layer disposed within the through hole of the insulating layer 211. For example, the second metal layer 221-2 of the circuit layer 221 may refer to a portion of one electroplating layer disposed outside the through hole.

Meanwhile, the circuit layer of the circuit board of the second embodiment shown in FIG. 10 may have a different number of layers from the circuit layer of the circuit board of the first embodiment shown in FIG. 9.

For example, the through electrode of the circuit board of the second embodiment may have substantially the same structure as the through electrode of the circuit board of the first embodiment.

However, the circuit layer 221 of the circuit board of the second embodiment may have a different number of layers from the circuit layer of the circuit board of the first embodiment.

For example, the circuit layer 221 of the circuit board of the second embodiment includes a first metal layer 221-1 and a second metal layer 221-2.

In this case, the first metal layer 221-1 of the circuit layer of the circuit board of the first embodiment includes a first-first metal layer 221-1a and a first-second metal layer 221-1b.

Alternatively, the first metal layer 221-1 of the circuit layer 221 of the circuit board of the second embodiment may be formed of a single layer. For example, the circuit layer 221 of the circuit board of the second embodiment may include only the first-second metal layer 221-1b in the first metal layer of the first embodiment.

That is, the circuit board of the second embodiment may be manufactured by a SAP method. In addition, in a process of forming the circuit layer by the SAP method, the copper foil layer or the copper foil corresponding to the first-first metal layer 221-1a disposed on a surface of the insulating layer may be removed. Accordingly, in the circuit board of the second embodiment, the first metal layer corresponding to the seed layer may include only the first-second metal layer 221-1b corresponding to the chemical copper plating layer. In addition, the first metal layer 221-1 corresponding to the first-second metal layer 221-1b of the second embodiment may be in direct contact with the upper surface of the insulating layer 211.

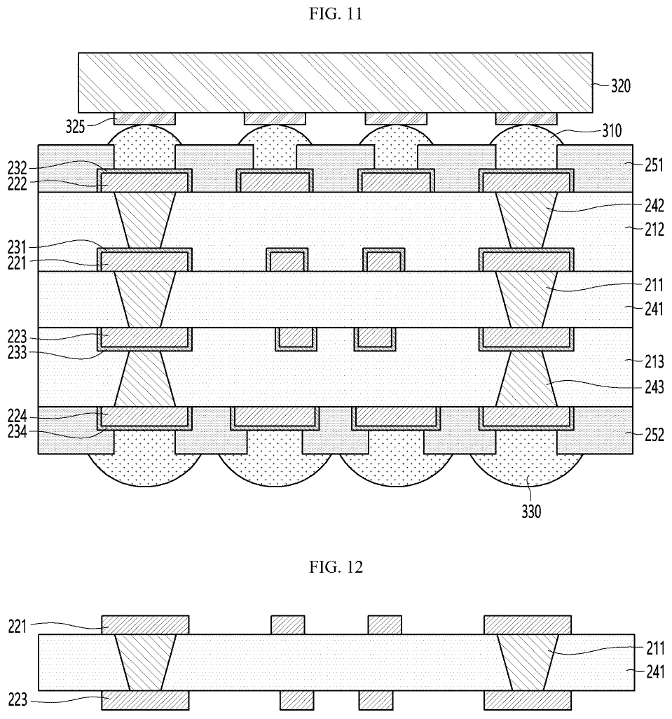

FIG. 11 is a view showing a semiconductor package according to an embodiment.

Referring to FIG. 11, the semiconductor package includes a chip mounted on a circuit board of the embodiment. The chip may be at least one. For example, the chip may be at least one processor chip. Alternatively, the chip may include at least two processor chips. Alternatively, the chip may include at least one processor chip and at least one memory chip.

The semiconductor package includes a first connection part 310. Specifically, a second circuit layer 222 disposed at an uppermost side of the circuit board includes a pad. In addition, the pad of the circuit layer 222 vertically overlaps with an opening of the first protective layer 251.

At this time, a buffer layer may not be formed on an upper surface of a circuit layer corresponding to the pad among the second circuit layers 222. Accordingly, the first connection part 310 may be directly disposed on the pad.

In addition, the first connection part 310 is disposed on the pad of the second circuit layer 222 that vertically overlaps the opening of the first protective layer 251.

The first connection part 310 may include a spherical shape. For example, a cross-section of the first connection part 310 may include a circular shape or a semicircular shape. For example, the cross-section of the first connection part 310 may include a partially or entirely rounded shape. For example, the cross-sectional shape of the first connection part 310 may be flat at one side and curved at other side. The first connection part 310 may be a solder ball, but is not limited thereto.

The semiconductor package may include a chip 320 or a device 320 disposed on the first connection part 310.

The chip 320 may be a processor chip. For example, the chip 320 may be an application processor (AP) chip of any one of a central processor (e.g., a CPU), a graphic processor (e.g., a GPU), a digital signal processor, an encryption processor, a microprocessor, and a microcontroller.

At this time, a terminal 325 may be provided on the lower surface of the chip 320, and the terminal 325 may be electrically connected to the second circuit layer 222 of the circuit board through the first connection part 310.

Meanwhile, the semiconductor package may include a plurality of chips that are disposed and spaced apart from each other in a horizontal direction on one circuit board.

For example, the chip 320 may include a first chip and a second chip that are spaced apart from each other. In addition, the first chip and the second chip may be different types of application processor (AP) chips.

Meanwhile, the first chip and the second chip may be spaced apart from each other by a certain distance on the circuit board. For example, a distance gap between the first chip and the second chip may be 150 um or less. For example, the distance between the first chip and the second chip may be 120 um or less. For example, the distance between the first chip and the second chip may be 100 um or less.

Preferably, for example, the distance between the first chip and the second chip may have a range of 60 um to 150 um. For example, the distance between the first chip and the second chip may have a range of 70 um to 120 um. For example, the distance between the first chip and the second chip may have a range of 80 um to 110 um. For example, if the distance between the first chip and the second chip is less than 60 um, a problem may occur in the operational reliability of the first chip or the second chip due to interference between the first chip and the second chip. For example, if the distance between the first chip and the second chip is greater than 150 um, as the distance between the first chip and the second chip increases, signal transmission loss may increase.

Meanwhile, the semiconductor package may include a second connection part 330. The second connection part 330 may be disposed on the lower surface of the fourth circuit layer 224. For example, the fourth circuit layer 224 includes at least one pad. In addition, the pad of the fourth circuit layer 224 may vertically overlap with the opening of the second protective layer 252. In addition, the second connection part 330 may be disposed under the pad of the fourth circuit layer 224 that vertically overlaps with the opening of the second protective layer 252. The second connection part 330 may be a solder ball, but is not limited thereto. The second connection part 330 may be for connecting a semiconductor package and a main board (or motherboard) of an external device. In addition, the fourth buffer layer 224 may not be formed on the lower surface of the fourth circuit layer 224 on which the second connection part 330 is disposed.

FIGS. 12 to 17 are views showing a manufacturing method of a circuit board according to an embodiment in the order of processes.

Referring to FIG. 12, the embodiment may proceed with a process of manufacturing an inner layer of a circuit board. For example, the embodiment prepares a first insulating layer 211. Then, the embodiment forms a first through electrode 241 passing through the first insulating layer 211, a first circuit layer 221 disposed on the upper surface of the first insulating layer 211, and a third circuit layer 223 disposed on the lower surface of the first insulating layer 211.

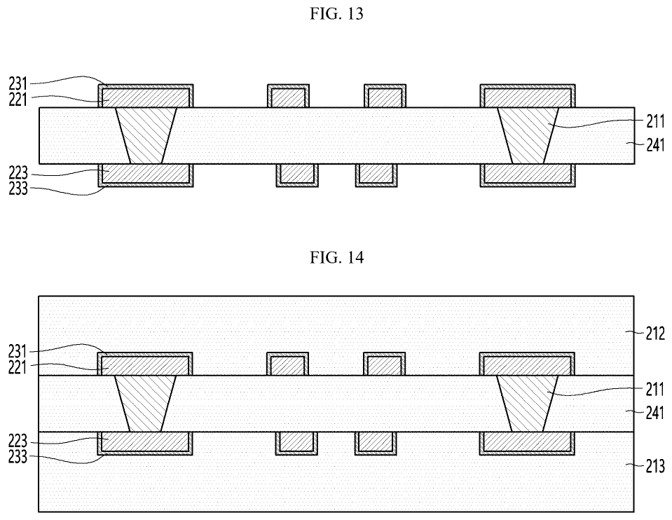

Next, referring to FIG. 13, the embodiment may plasma-treat the surfaces of the first circuit layer 221 and the third circuit layer 223 using nitrogen (N). As a result, a nitride layer containing nitrogen (N) may be formed on the surfaces of the first circuit layer 221 and the third circuit layer 223. For example, a functional group containing nitrogen (N) may be generated on the surfaces of the first circuit layer 221 and the third circuit layer 223. At this time, the functional group containing nitrogen (N) may be formed not only on the first circuit layer 221 and the third circuit layer 223, but also on the upper and lower surfaces of the first insulating layer 211.

Next, the embodiment forms a first buffer layer 231 containing a first functional group 130a and a second functional group 130c on the first circuit layer 221. In addition, the embodiment forms a third buffer layer 233 including a first functional group 130a and a second functional group 130c on the third circuit layer 223.

Next, referring to FIG. 14, the embodiment forms a second insulating layer 212 on the first insulating layer 211. In addition, the embodiment forms a third insulating layer 213 under the first insulating layer 211. At this time, the second insulating layer 212 may include a functional group covalently bonded with the second functional group 130c of the first buffer layer 231. As a result, adhesion between the second insulating layer 212 and the first circuit layer 221 can be secured. In addition, the third insulating layer 213 may include a functional group covalently bonded with the second functional group 130c of the third buffer layer 233. As a result, adhesion between the third circuit layer 223 and the third insulating layer 213 can be secured.

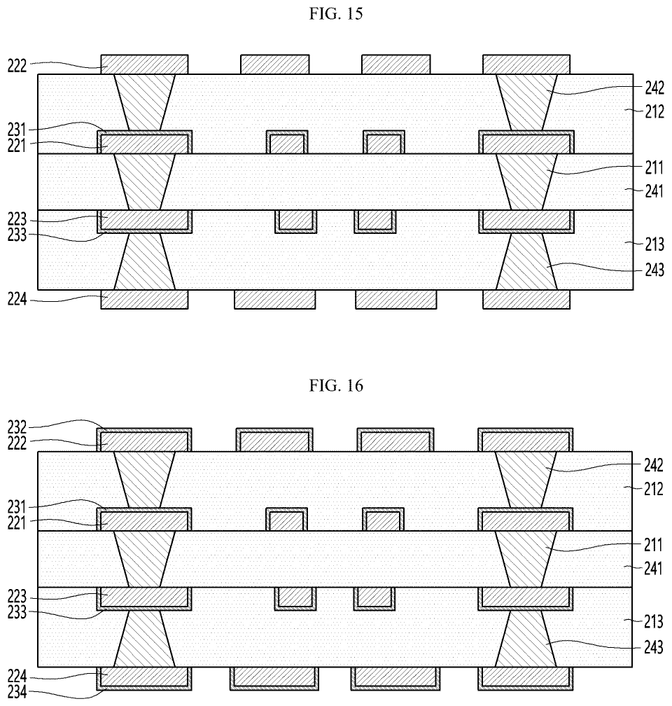

Next, referring to FIG. 15, the embodiment may proceed with a process of forming an outer layer of a circuit board.

Specifically, the embodiment may proceed with a process of forming a second through electrode 242 passing through the second insulating layer 212 and a second circuit layer 222 disposed on an upper surface of the second insulating layer 212. In addition, the embodiment may proceed with a process of forming a third through electrode 243 passing through the third insulating layer 213 and a fourth circuit layer 224 disposed on a lower surface of the third insulating layer 213.

Next, referring to FIG. 16, the embodiment may perform plasma treatment on the surfaces of the second circuit layer 222 and the fourth circuit layer 224 using nitrogen (N). As a result, a nitride layer containing nitrogen (N) may be formed on the surfaces of the second circuit layer 222 and the fourth circuit layer 224. For example, a functional group including nitrogen (N) may be generated on the surface of the second circuit layer 222 and the surface of the fourth circuit layer 224. At this time, the functional group including nitrogen (N) may be formed not only on the second circuit layer 222 and the fourth circuit layer 224, but also on the upper surface of the second insulating layer 212 and the lower surface of the third insulating layer 213.

Next, the embodiment forms a second buffer layer 232 including a first functional group 130a and a second functional group 130c on the second circuit layer 222. In addition, the embodiment forms a fourth buffer layer 234 including a first functional group 130a and a second functional group 130c on the fourth circuit layer 224.

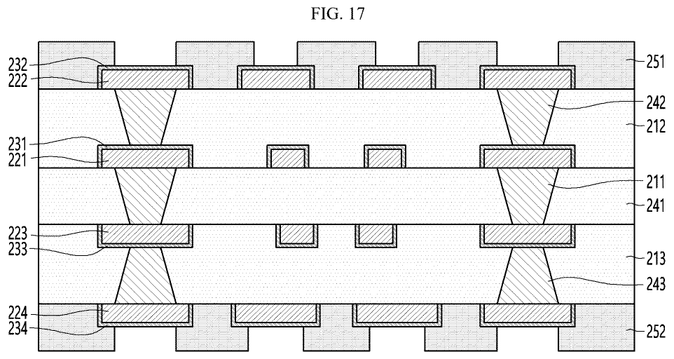

Next, referring to FIG. 17, the embodiment forms a first protective layer 251 on the second insulating layer 212. In addition, the embodiment forms a second protective layer 252 on the third insulating layer 213.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristic, structure, and effect illustrated in each embodiment may be combined or modified for other embodiments by a person skilled in the art. Thus, it would be construed that contents related to such a combination and such a modification are included in the scope of the present invention.

Embodiments are mostly described above. However, they are only examples and do not limit the present invention. A person skilled in the art may appreciate that several variations and applications not presented above may be made without departing from the essential characteristic of embodiments. For example, each component particularly represented in the embodiments may be varied. In addition, it should be construed that differences related to such a variation and such an application are included in the scope of the present invention defined in the following claims.

1. A circuit board comprising:
a first insulating layer;
a first circuit layer disposed on the first insulating layer;
a first buffer layer disposed on the first circuit layer; and
a second insulating layer disposed on the first insulating layer and the first buffer layer,
wherein the first circuit layer includes a metal layer disposed on the first insulating layer, and a surface layer corresponding to a nitride layer of the metal layer disposed on the metal layer and including nitrogen (N).

2. The circuit board of claim 1, wherein the first buffer layer includes:
a first functional group bonded to the surface layer; and
a second functional group bonded to the second insulating layer.

3. The circuit board of claim 2, wherein the first circuit layer includes a third functional group including nitrogen (N) that is provided on the surface layer and coordinately bonds with the first functional group.

4. The circuit board of claim 2, wherein the first functional group includes at least one azole group among diazole, triazole, tetra azole, benzo triazole, benzo thiazole, and nitro triazole.

5. The circuit board of claim 2, wherein the second functional group includes a siloxane group covalently bonded to the second insulating layer.

6. The circuit board of claim 2, wherein the first buffer layer is formed with an organic silane agent including an azole group corresponding to the first functional group.

7. The circuit board of claim 2, wherein the first insulating layer includes a first region overlapping the first circuit layer in a thickness direction, and a second region excluding the first region, and
wherein a fourth functional group including nitrogen (N) is provided on an upper surface of the second region of the first insulating layer.

8. The circuit board of claim 1, wherein the first circuit layer includes a first surface in contact with the first buffer layer, and
wherein a roughness (Ra) of the first surface of the first circuit layer satisfies a range of 0.1 um to 0.9 um.

9. The circuit board of claim 8, wherein the first circuit layer includes a second surface in contact with the first insulating layer, and
wherein a roughness (Ra) of the second surface of the first circuit layer is different from the roughness (Ra) of the first surface.

10. The circuit board of claim 8, wherein a roughness (Ra) of the first buffer layer corresponds to the roughness (Ra) of the first surface of the first circuit layer.

11. The circuit board of claim 7, wherein the first buffer layer includes a first portion disposed between the surface layer of the first circuit layer and the second insulating layer, and a second portion disposed between the first insulating layer and the second insulating layer.

12. The circuit board of claim 11, wherein the first portion of the first buffer layer is bonded with the nitrogen of the surface layer of the first circuit layer, and
wherein the second portion of the first buffer layer is bonded with the nitrogen (N) provided in the second region of the first insulating layer.

13. The circuit board of claim 8, wherein the first buffer layer has a thickness of 10 nm to 50 nm.

14. The circuit board of claim 8, comprising:
a through electrode passing through at least one of the first insulating layer and the second insulating layer, and
wherein a roughness (Ra) of a side surface of the through electrode is different from the roughness (Ra) of the first surface of the first circuit layer.

15. The circuit board of claim 14, wherein the first buffer layer does not contact a lower surface of the through electrode.

16. The circuit board of claim 14, wherein a lower surface of the through electrode is in direct contact with an upper surface of the metal layer.

17. The circuit board of claim 2, comprising:
a second circuit layer disposed on the second insulating layer;
a second buffer layer disposed on the second circuit layer; and
a first protective layer disposed on the second insulating layer and the second buffer layer,
wherein the second buffer layer has functional groups corresponding to the first and second functional groups of the first buffer layer.

18. The circuit board of claim 3, wherein the first buffer layer includes a metal ion that coordinately bonds with the first functional group or the third functional group.

19. The circuit board of claim 17, wherein the second circuit layer includes a second metal layer and a second surface layer that is a nitride layer of the second metal layer, and
wherein the first protective layer includes an opening that overlaps the second circuit layer along a vertical direction, and
wherein the second surface layer does not overlap the opening along the vertical direction.

20. The circuit board of claim 19, wherein the second metal layer includes a portion provided in a region that overlaps the opening along the vertical direction, and
wherein an electronic device is disposed on the portion of the second metal layer.
